(19) United States
(12) Patent Application Publication
(10) Pub. No.: US 2009/0020837 A1
(43) Pub. Date: Jan. 22, 2009

(54) Semiconductor device and manufacturing method thereof

(75) Inventor: Shian-Jyh Lin, Chiayi County (TW)

Correspondence Address: ATTN: Juan Carlos A. Marquez;REED SMITH LLP, Suite 1400, 3110 Fairview Park Drive, Falls Church, VA, 22042, US

(73) Assignee: Nanya Technology Corp.

(21) Appl. No.: 12/007,941

(22) Filed: Jan. 17, 2008

(30) Foreign Application Priority Data
Jul. 18, 2007 (TW) 096126115

(51) Int. Cl. H01L 29/78; H01L 21/336; H01L 21/306

(52) U.S. Cl. 257/412; 438/282; 438/745; 257/E21.215; 257/E21.428; 257/E29.27

(57) ABSTRACT

A long channel semiconductor device and a manufacturing method thereof are provided. The method for forming a long channel semiconductor device includes: providing a substrate; forming a trench in the substrate with a trench bottom defining a first channel length; forming a spacer on a sidewall of the trench; recessing the trench bottom to form a recessed bottom defining a second channel length longer than the first channel length; forming a gate dielectric layer on the recessed bottom; forming a gate conductor on the gate dielectric layer; and forming source/drain regions in the substrate adjacent to the spacer.

### CROSS REFERENCE TO RELATED APPLICATIONS

This application claims the right of priority based on Taiwan Patent Application No. 096126115 entitled “Semiconductor Device with Long Channel and Manufacturing Method thereof,” filed on Jul. 18, 2007, which is incorporated herein by reference and assigned to the assignee herein.

### FIELD OF THE INVENTION

This invention relates to a semiconductor device and a manufacturing method thereof, and more particularly, relates to a semiconductor device having a recessed channel and a manufacturing method thereof.

### BACKGROUND OF THE INVENTION

Over the years, the silicon-based integrated circuit technology including field effect transistor (FET) and/or MOSFET component has been developed to provide a higher speed and higher density circuit to improve the device performance. In general, a transistor in a substrate has heavily doped source/drain (S/D) regions separated from each other by a lightly doped channel region. The channel region can be controlled using a gate electrode separated from the channel region by a gate dielectric layer.

In semiconductor industry, it is a common target to minimize the size of the transistor in the integrated circuit. The transistor can be scaled down by reducing the feature size, such as the gate length, the thickness of the gate oxide layer and the junction depth, and increasing the channel-doping level.

However, the shrink of a MOS transistor usually accompanies the short channel effects. The short channel effects may cause an unexpected threshold voltage drop, increase parasitic capacitance between the junction region and the substrate, and increase leakage current. Therefore, it is desired to provide a transistor having a longer channel length for reducing or avoiding the short channel effects.

### SUMMARY OF THE INVENTION

According to one aspect of the present invention, a recessed channel semiconductor device and a method for manufacturing the same are provided. In comparison with a planar channel within a conventional transistor, the present invention provides a transistor with a recessed channel so as to increase the channel length, resulting in the elimination of the short channel effects that adversely affect the transistor performance.

In one embodiment, the present invention provides a recessed channel semiconductor device and a manufacturing method thereof. The method for manufacturing the recessed channel semiconductor device includes: providing a substrate; forming a trench in the substrate with a trench bottom defining a first channel length; forming a spacer on a sidewall of the trench; recessing the trench bottom to form a recessed bottom defining a second channel length longer than the first channel length; forming a gate dielectric layer on the recessed bottom; forming a gate conductor on the gate dielectric layer; and forming source/drain regions in the substrate adjacent to the spacer.

According to another aspect of the present invention, a recessed channel semiconductor device, such as a transistor, is provided. The long channel semiconductor device includes: a substrate; a trench in the substrate, wherein the trench has a recessed bottom; a spacer on a sidewall of the trench; a gate dielectric layer on the recessed bottom surface; a gate on the gate dielectric layer and adjacent to the spacer; and source/drain regions in the substrate adjacent to the spacer.

### BRIEF DESCRIPTION OF THE DRAWINGS

FIG. 1 to FIG. 5 are cross-sectional views showing the process of manufacturing a recessed channel semiconductor device in accordance with an embodiment of the present invention.

### DETAILED DESCRIPTION OF THE INVENTION

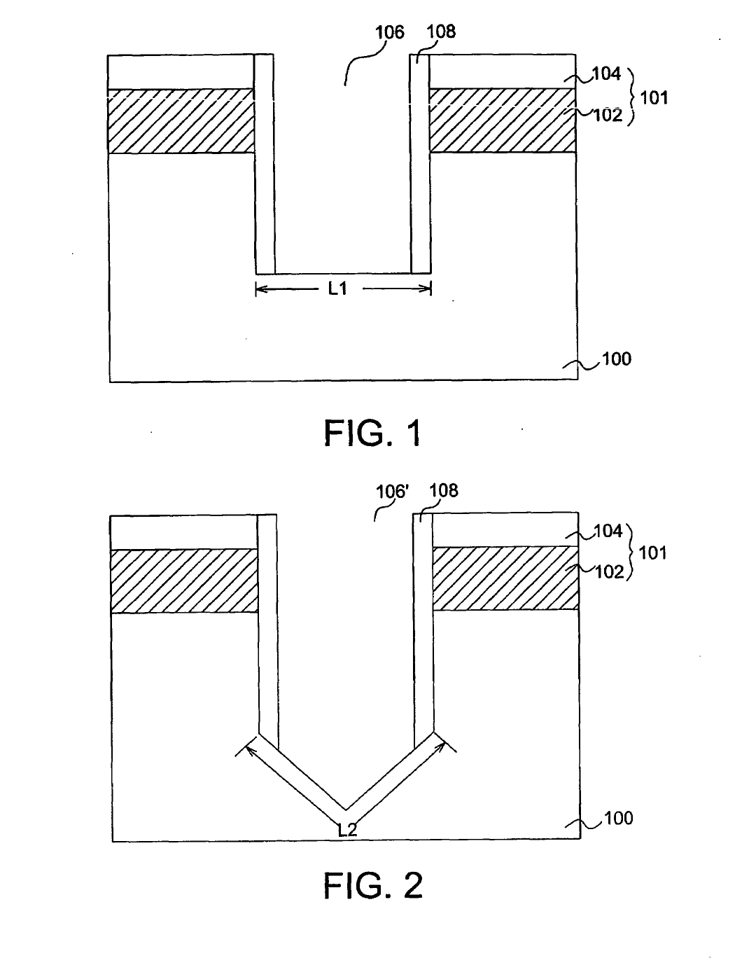

The present invention provides a recessed channel semiconductor device and a manufacturing method thereof. The present invention would be described in detail by referring to the following description in conjunction with the accompanying drawings from FIG. 1 to FIG. 5.

Referring to FIG. 1, the present invention provides a method for manufacturing a recessed channel semiconductor device, such as a transistor. In one embodiment of the present invention, the method includes providing a substrate 100, such as a silicon substrate, a germanium substrate, a silicon germanium substrate, a silicon-on-insulator (SOI) substrate, a SiGe-on-insulator (SGeOI) substrate and the like. In this embodiment, the substrate 100 can be a silicon wafer, for example. Subsequently, a hard mask 101 is formed on the substrate 100. The hard mask 101 can include an oxide layer 102 formed by an oxidation process, and a nitride layer 104 deposited on the oxide layer 102.

Then, a patterned photoresist (not shown) is formed to define a trench 106. By using the patterned photoresist as a mask, an opening (not shown) is formed in the hard mask 101, and then the substrate 100 is etched to form the trench 106 with a trench bottom 105. It should be noted that the trench bottom 105 is substantially a planar bottom, which defines a first length L1 as shown in FIG. 1. A spacer 108 is then formed on a sidewall of the trench 106. The step of forming the spacer 108 includes depositing a conformal dielectric layer, such as a silicon oxide layer or a silicon nitride layer, on the hard mask layer 101 and the trench 106. Then, the conformal dielectric layer is anisotropically etched, for example, to expose the surface of the hard mask layer 101 and a portion of the trench bottom 105, and remain a portion of the dielectric layer covering the sidewall of the trench 106.

Referring to FIG. 2, the exposed trench bottom 105 is then recessed to form a recessed bottom 105′ defining a second channel length L2, which is longer than the first channel length, L1. For example, the planar trench bottom 105 is recessed to form the recessed bottom 105′ in this embodiment. In the embodiment, an ammonium hydroxide (NH₄OH) solution is utilized as an etching solution to etch the substrate 100 along about 45° degree with respect to the crystal orientation <110> of the silicon wafer, so that the recessed bottom 105′ can be formed. In general, the recessed bottom 105′ is with a point end after the etching process. The recessed bottom 105′ defines a second channel length L2. As shown in FIG. 1, the original circuit path is through a channel defined by the trench bottom 105 with the first channel length L1. After the step of recessing the trench bottom 105 to form the recessed bottom 105′, the circuit path is through a channel defined by the recessed bottom 105′ with the second channel length L2. It is apparently shown that the second channel length L2 is longer than the first channel length L1 due to the recessing process.

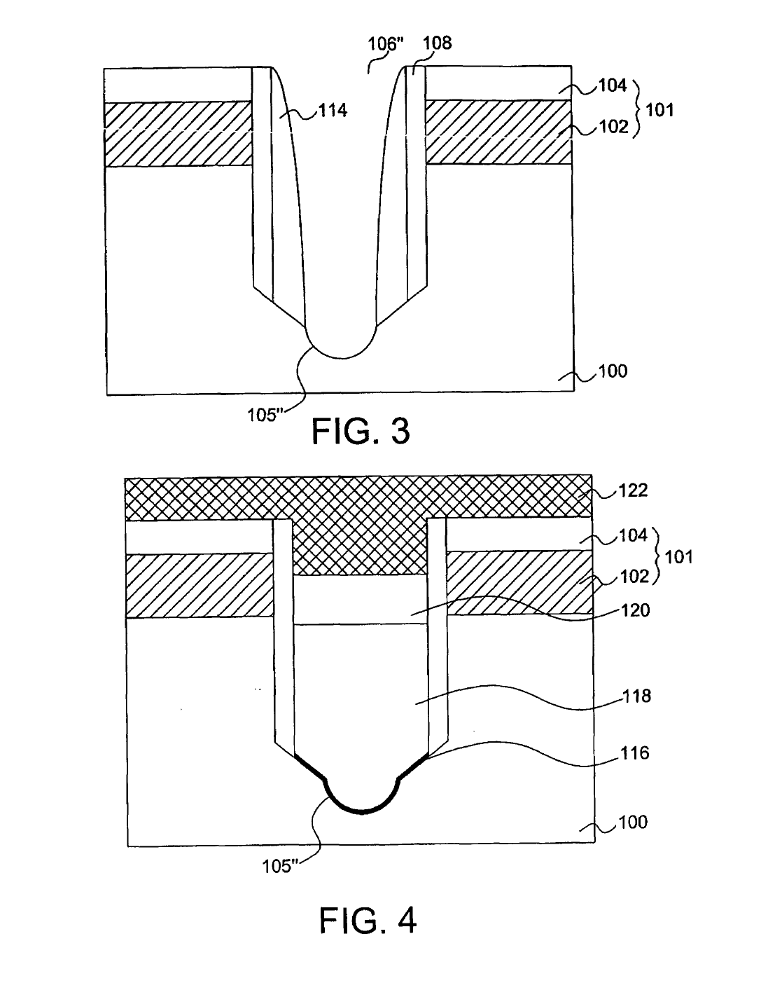

Referring to FIG. 3, in order to prevent the point discharge and to increase the current intensity, the recessed bottom 105′ is preferably rounded. For example, a dielectric layer 114, such as a silicon oxide layer or a silicon nitride layer, is formed to cover the spacer 108 on the sidewall of the trench 106′ and a portion of the recessed bottom 105′. Then, the uncovered portion of the recessed bottom 105′ is etched by using the dielectric layer 114 as a hard mask to form a curve bottom 105″. In this embodiment, a mixed solution of nitric acid and hydrofluoric acid is utilized to etch the V-sharp bottom 105′ creating a curve bottom 105″. Subsequently, the dielectric layer 114 is removed and a trench 106″ is formed.

Next steps are to form a transistor in the trench 106″. Referring to FIG. 4, a gate dielectric layer 116 is formed on the bottom surface of the trench 106″, for example, by a thermal oxidation process, and then a gate electrode 128 is formed on the gate dielectric layer 116. The step of forming the gate electrode 128 sequentially includes depositing a gate conductor 118, a metal or metal silicide layer 120, and a cap nitride layer 122 on the gate dielectric layer 116. In the instance, the gate conductor 118 is deposited on the substrate 100 and fills the trench 106″. Then, a chemical mechanical polishing (CMP) process is performed on the gate conductor 118 to expose the hard mask layer 101, and the polished gate conductor 118 is then etched back to a depth by any suitable prior art etching technology. Furthermore, the metal or metal silicide layer 120 is formed on the gate conductor 118, and the cap nitride layer 122 is formed on the metal or metal silicide layer 120. The metal or metal silicide layer 120 and the cap nitride layer 122 are formed by any suitable prior art depositing and/or etching processes without discussion in any detail herein.

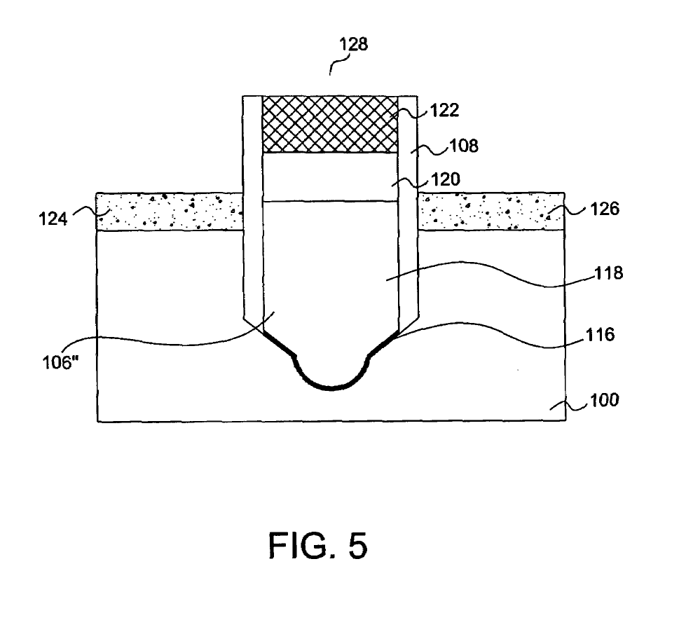

Subsequently, source/drain regions 124, 126 are formed in the substrate 100 adjacent to the spacer 108 using an ion implantation process or a thermal diffusion process. In this embodiment, the ion implantation process is performed to form the source/drain regions 124, 126. The hard mask layer 101 is removed before the source/drain region 124, 126 are formed, and a semiconductor device with a recessed channel is formed, as shown in FIG. 5.

Referring to FIG. 5, the present invention also provides a semiconductor device with a recessed channel, such as a MOS transistor. In one embodiment, the MOS transistor includes a substrate 100 having a trench 106″, a spacer 108, a gate dielectric layer 116, a gate electrode 128, and source/drain regions 124, 126. In this embodiment, the substrate 100 can be a silicon substrate, a germanium substrate, a silicon germanium substrate, a silicon-on-insulator (SOI) substrate, a SiGe-on-insulator (SGeOI) substrate and the like. The gate dielectric layer 116 can be an oxide layer and the like. The gate electrode 128 sequentially includes a gate conductor 118, such as a polysilicon layer, a metal/metal silicide layer 120, and a cap nitride layer 122. The metal/metal silicide layer 120 includes a material selected from a group consisting of tungsten, tungsten nitride, titanium nitride, titanium-tungsten alloy, tungsten silicide, and the combination thereof. The source/drain regions 124, 126 are formed by a doping process, such as ion implantation or thermal diffusion.

The trench 106″ formed in the substrate 100 has a recessed bottom 105″, which defines a non-linear channel region, such as a rounded shape trench bottom. The channel region defined by the recessed bottom 105″ is larger than the channel region defined by a prior art trench with a planar bottom. For the prior art trench, the current path between the source/drain regions is along the horizontal surface of the bottom of the trench, which is substantially a linear path. In the trench 106″ with the recessed bottom 105″ in this embodiment (as shown in FIG. 4 or FIG. 5), the current path between the source/drain regions 124, 126 is along the curve surface of the bottom of the trench, which is substantially a non-linear path. Accordingly, with a same trench width, the non-linear channel is apparently longer than the linear channel, so that the current path between the source/drain regions 124, 126 is longer.

Moreover, the spacer 108 is on the sidewall of the trench 106″. In this embodiment, the spacer 108 is protruding above the surface of the substrate 100. The gate dielectric layer 116 is on the bottom of the trench 106″, i.e. the channel region of the recessed bottom 105″. The gate conductor 118 is disposed on the gate dielectric layer 116 and adjacent to the spacer 108. The metal/metal silicide layer 120 is deposited on the gate conductor 118, and the cap nitride layer 122 is on the metal layer 120. The source/drain regions 124, 126 are in the substrate 100 adjacent to the spacer 108. Therefore, the present invention provides a transistor structure with a longer channel length so as to reduce the short channel effect, and the process for forming the transistor structure can be easily integrated with the current process flow.

Although specific embodiments have been illustrated and described, it will be obvious to those skilled in the art that various modifications may be made without departing from what is intended to be limited solely by the appended claims.

1. A method for forming a semiconductor device with a recessed channel comprising:
providing a substrate;
forming a trench in said substrate;
forming a spacer on a sidewall of said trench;
recessing a bottom of said trench to form a recessed bottom with a conical sidewall and an arcuate tip immediately adjacent to said conical sidewall;
forming a gate dielectric layer on a surface of said recessed bottom;
forming a gate conductor on said gate dielectric layer; and
forming source/drain regions in said substrate adjacent to said spacer.

2. The method of claim 1, wherein said bottom recessing step comprises utilizing an ammonium hydroxide (NH₄OH) solution to recess said bottom of said trench.

3. The method of claim 1, wherein said bottom recessing step comprises:
etching said bottom of said trench to form a pointed bottom;
forming a dielectric layer on said spacer to cover a portion of said pointed bottom;
etching said pointed bottom to form an arcuate bottom; and
removing said dielectric layer.

4. The method of claim 3, wherein said bottom of said trench etching step comprises utilizing a mixed solution of nitric acid and hydrofluoric acid.

5. The method of claim 1, wherein said step of forming said source/drain regions comprises an ion implantation process.

6. A semiconductor device comprising:
a substrate;
a trench in said substrate, wherein said trench has a vertical sidewall and a recessed bottom and said recessed bottom is formed with a conical sidewall and an arcuate tip;
a spacer on said vertical sidewall of said trench;
a gate dielectric layer on said recessed bottom;
a gate formed in said trench, and being in contact with said gate dielectric layer; and
source/drain regions formed in said substrate and adjacent to said spacer.

7. The semiconductor device of claim 6, wherein said gate on said gate dielectric layer sequentially comprises a gate conductor, a metal layer, and a cap nitride layer.

8. The semiconductor device of claim 7, wherein said gate conductor comprises a polysilicon layer.

9. The semiconductor device of claim 7, wherein said metal layer comprises a material selected from a group consisting of tungsten, tungsten nitride, titanium nitride, titanium-tungsten alloy, tungsten silicide, and the combination thereof.

10. A method for forming a trench in a semiconductor substrate comprising:
forming a trench with a sidewall and a bottom in said semiconductor substrate;
forming a first spacer on said sidewall;
recessing the bottom of said trench to form a conical bottom;
forming a second spacer on said first spacer to partially expose said conical bottom; and
rounding said exposed conical bottom to form an arcuate bottom in said semiconductor substrate.

11. The method of claim 10, wherein said conical bottom rounding step comprises performing a wet etching process to etch said exposed conical bottom.
